(19) United States
(12) Patent Application Publication
(10) Pub. No.: US 2023/0180503 A1
(43) Pub. Date: Jun. 8, 2023

(54) LIGHT EMITTING DEVICE AND DISPLAY DEVICE INCLUDING THE SAME

(71) Applicant: Samsung Display Co., LTD., Yongin-si (KR)

(72) Inventors: Yoonseok KA, Seoul (KR); Ji Young MOON, Gwangju-si (KR); Hakchoong LEE, Hwaseong-si (KR); Pilgu KANG, Hwaseong-si (KR); Dong Chan KIM, Suwon-si (KR); Ha Jin SONG, Hwaseong-si (KR); Jung Ho CHOI, Yongin-si (KR); Jae Hoon HWANG, Seoul (KR)

(73) Assignee: Samsung Display Co., LTD., Yongin-si (KR)

(21) Appl. No.: 17/900,271

(22) Filed: Aug. 31, 2022

(30) Foreign Application Priority Data
Dec. 2, 2021 (KR) 10-2021-0170936

(51) Int. Cl. H01L 51/50; H01L 27/32

(52) U.S. Cl. CPC H01L 51/5068; H01L 27/3244; H01L 51/502; H01L 51/5084

(57) ABSTRACT

An embodiment provides a light emitting device including: a first electrode; a second electrode overlapping the first electrode in a plan view; and a light emitting part disposed between the first electrode and the second electrode. The second electrode includes a first layer disposed on the light emitting part and including a first organic material, and a metal thin film layer disposed on the first layer and including a first metal. The light emitting part includes an emission layer, a hole transport region disposed between the first electrode and the emission layer, and an electron transport region disposed between the emission layer and the second electrode. The first layer is disposed on the electron transport region.

### CROSS-REFERENCE TO RELATED APPLICATION(S)

This application claims priority to and the benefit of Korean Patent Application No. 10-2021-0170936 under 35 U.S.C. § 119, filed on Dec. 02, 2021, in the Korean Intellectual Property Office (KIPO), the disclosure of which is incorporated by reference herein in its entirety.

### BACKGROUND

### 1. Technical Field

The disclosure relates to a light emitting device and a display device including the same.

### 2. Description of the Related Art

A light emitting device is a device having a characteristic in which electrical energy is converted into light energy. Examples of such a light emitting device include an organic light emitting device using an organic material for an emission layer, and a quantum dot light emitting device using a quantum dot for an emission layer.

The light emitting device may include a first electrode and a second electrode that overlap each other, a hole transport region, an emission layer, and an electron transport region, which are disposed between the first electrode and the second electrode. Holes injected from the first electrode move to the emission layer through the hole transport region, and electrons injected from the second electrode move to the emission layer through the electron transport region. The holes and electrons are combined in the emission layer region to generate excitons. Light is generated as the excitons are changed into a ground state from an exited state.

The above information disclosed in this Background section is only for enhancement of understanding of the background of the disclosure, and therefore it may contain information that does not form the prior art that is already known in this country to a person of ordinary skill in the art.

### SUMMARY

Embodiments are to provide an electrode including a metal with a thin thickness. Embodiments are to provide an electrode that has excellent film quality to provide improved conductivity and transmittance. Embodiments are to provide a light emitting device including an electrode, and to provide a display device having improved quality by including the light emitting device.

An embodiment provides a light emitting device that may include: a first electrode; a second electrode overlapping the first electrode in a plan view; and a light emitting part disposed between the first electrode and the second electrode. The second electrode may include: a first layer disposed on the light emitting part and including a first organic material; and a metal thin film layer disposed on the first layer and including a first metal. The light emitting part may include: an emission layer; a hole transport region disposed between the first electrode and the emission layer; and an electron transport region disposed between the emission layer and the second electrode. The first layer may be disposed on the electron transport region.

The first organic material may form a coordination bond with the first metal.

The first layer may further include at least one of a phenanthroline group, a pyrene group, a furan group, and a thiol group.

The first layer may further include a second metal doped into the first organic material.

The second metal may include at least one of Yb, Li, Cu, Ag, Au, Al, and Mg.

The first metal of the metal thin film layer may be one of Ag, Au, Cu, Al, and Mg.

The second electrode may further include a holding layer disposed on the metal thin film layer.

The holding layer may include a second organic material, and the second organic material may form a coordination bond with the first metal of the metal thin film layer.

The second organic material may include at least one of a phenanthroline group, a pyrene group, a furan group, and a thiol group.

The holding layer may include a third metal doped into the second organic material.

The third metal may include at least one of Yb, Li, Cu, Ag, Au, Al, and Mg.

Another embodiment provides a display device that may include: a transistor disposed on a substrate; and a light emitting device electrically connected to the transistor. The light emitting device may include: a first electrode; a second electrode overlapping the first electrode in a plan view; and a light emitting part disposed between the first electrode and the second electrode. The second electrode may include: a first layer disposed on the light emitting unit and including a first organic material; and a metal thin film layer disposed on the first layer and including a first metal. The first organic material may include at least one of a phenanthroline group, a pyrene group, a furan group, and a thiol group.

The first organic material may form a coordination bond with the first metal.

The first layer may further include a second metal doped into the first organic material.

The second metal may include at least one of Yb, Li, Cu, Ag, Au, Al, and Mg.

The first metal of the metal thin film layer may be one of Ag, Au, Cu, Al, and Mg.

The second electrode may further include a holding layer disposed on the metal thin film layer, and the holding layer may include a second organic material.

The second organic material may include at least one of a phenanthroline group, a pyrene group, a furan group, and a thiol group.

The holding layer may include a third metal doped into the second organic material, and the third metal may include at least one of Yb, Li, Cu, Ag, Au, Al, and Mg.

A thickness of the holding layer may be in a range of about 10 angstroms to about 700 angstroms.

According to the embodiments, it is possible to provide an electrode including a metal with a thin thickness. According to the embodiments, it is possible to provide an electrode that has excellent film quality to provide improved conductivity and transmittance. According to the embodiments, it is possible to provide a light emitting device including an electrode, and to provide a display device having improved quality by including the light emitting device.

### BRIEF DESCRIPTION OF THE DRAWINGS

FIG. 1 illustrates a schematic cross-sectional view of a light emitting device according to an embodiment.

FIG. 2 and FIG. 3 respectively illustrate a schematic cross-sectional view of a second electrode according to an embodiment.

FIG. 4, FIG. 5, and FIG. 6 respectively illustrate a schematic cross-sectional view of a second electrode according to an embodiment.

FIG. 7 illustrates a schematic cross-sectional view of a light emitting device according to an embodiment.

FIG. 8 illustrates an exploded perspective view of a display device according to an embodiment.

FIG. 9 illustrates a schematic cross-sectional view of a display panel according to an embodiment.

FIG. 10 illustrates a schematic cross-sectional view of a display panel according to an embodiment.

FIG. 11 illustrates a graph of sheet resistance of second electrodes according to a comparative example and an example.

FIG. 12 illustrates a graph of sheet resistance of second electrodes according to a comparative example and an example.

FIG. 13 illustrates a graph of an amount of change in sheet resistance of second electrodes according to a comparative example and an example.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the embodiment, parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

The expression “(an interlayer) includes at least one compound represented by Formula 1” as used herein may include a case in which “(an interlayer) includes one or more identical compounds represented by Formula 1” and a case in which “(an interlayer) includes two or more different compounds represented by Formula 1”.

The term “group” as used herein refers to a group of the IUPAC periodic table of the elements.

The term “alkali metal” as used herein refers to group 1 elements. Specifically, the alkali metal may be lithium (Li), sodium (Na), potassium (K), rubidium (Rb), or cesium (Cs).

The term “alkaline earth metal” as used herein refers to group 2 elements. Specifically, the alkaline earth metal may be magnesium (Mg), calcium (Ca), strontium (Sr), or barium (Ba).

The term “lanthanum metal” as used herein refers to lanthanum and lanthanoid elements in the periodic table. Specifically, the lanthanum metal may be lanthanum (La), cerium (Ce), praseodymium (Pr), neodymium Nd, promethium (Pm), samarium (Sm), europium (Eu), gadolinium (Gd), terbium (Tb), dysprosium (Dy), holmium (Ho), erbium (Er), thulium (Tm), ytterbium (Yb), or ruthenium (Ru).

The term “transition metal” as used herein refers to elements that belong to periods 4 to 7 and groups 3 to 12. Specifically, the transition metal may be titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), or cadmium (Cd).

The term “late transition metal” as used herein refers to metal elements that belong to one of period 4 to period 7 and simultaneously belong to one of group 13 to group 17. Specifically, the late transition metal may be aluminum (Al), gallium (Ga), indium (In), thallium (TI), tin (Sn), lead (Pb), bismuth (Bi), or polonium (Po).

The term “halogen” as used herein refers to group 17 elements. Specifically, the halogen may be fluorine (F), chlorine (Cl), bromine (Br), or iodine (I).

The term “inorganic semiconductor compound” as used herein may refer to all compounds being an inorganic material and having a band gap of less than 4 eV. Specifically, the inorganic semiconductor compound may include a halide of a lanthanoid metal, a halide of a transition metal, a halide of a late transition metal, tellurium, a telluride of a lanthanoid metal, a telluride of a transition metal, a telluride of a late transition metal, a selenide of a lanthanoid metal, a selenide of a transition metal, a selenide of a late transition metal, or any combination thereof. More specifically, the inorganic semiconductor compound may include EuI2, YbI2, SmI2, TmI2, AgI, CuI, NiI2, CoI2, Bih, PbI2, SnI2, Te, EuTe, YbTe, SmTe, TmTe, EuSe, YbSe, SmSe, TmSe, ZnTe, CoTe, ZnSe, CoSe, Bi₂Te₃, Bi₂Se₃, or any combination thereof.

The term “inorganic insulation compound” as used herein may refer to all compounds being an inorganic material and having a band gap of at least 4 eV. Specifically, the inorganic insulation compound may include a halide of an alkali metal, a halide of an alkaline earth metal, a halide of a lanthanoid metal, or any combination thereof. More specifically, the inorganic insulation compound may include NaI, KI, RbI, CsI, NaCl, KCI, RbCl, CsCI, NaF, KF, RbF, CsF, MgI2, CaI₂, SrI₂, BaI2, MgC1₂, CaC1₂, SrC1₂, BaC1₂, MgF₂, CaF₂, SrF₂, BaF₂, EuI₃, YbI₃, SmI₃, TmI₃, EuC1₃, YbC1₃, SmC1₃, TmC1₃, EuF₃, YbF₃, SmF₃, TmF₃, or any combination thereof.

The term “halide of an alkali metal” as used herein refers to a compound in which an alkali metal and a halogen are ionically bonded. Specifically, the halide of the alkali metal may include NaI, KI, RbI, CsI, NaCl, KC1, RbCl, CsC1, NaF, KF, RbF, CsF, or any combination thereof.

The term “halide of an alkaline earth metal” as used herein refers to a compound in which an alkaline earth metal and a halogen are ionically bonded. Specifically, the halide of the alkaline earth metal may include MgI₂, CaI₂, SrI₂, BaI₂, MgC1₂, CaC1₂, SrC1₂, BaC1₂, MgF₂, CaF₂, SrF₂, BaF₂, or any combination thereof.

The term “halide of a lanthanoid metal” as used herein refers to a compound in which a lanthanoid metal and a halogen are ionically bonded and/or covalently bonded. Specifically, the halide of the lanthanoid metal may include EuI₂, YbI₂, SmI₂, TmI₂, EuI₃, YbI₃, SmI3, TmI₃, EuC1₃, YbC1₃, SmC1₃, TmC1₃, EuF₃, YbF₃, SmF₃, TmF₃, or any combination thereof.

The term “halide of a transition metal” as used herein refers to a compound in which a transition metal and a halogen are ionically bonded and/or covalently bonded. Specifically, the halide of the transition metal may include AgI, CuI, NiI₂, CoI₂, or any combination thereof.

The term “halide of a late transition metal” as used herein refers to a compound in which a late transition metal and a halogen are ionically bonded and/or covalently bonded. Specifically, the halide of the late transition metal may include BiI₃, PbI₂, SnI₂, or any combination thereof.

The term “telluride of a lanthanoid metal” as used herein refers to a compound in which a lanthanoid metal and tellurium (Te) are ionically bonded, covalently bonded, and/or metallically bonded. Specifically, the telluride of the lanthanoid metal may include EuTe, YbTe, SmTe, TmTe, or any combination thereof.

The term “telluride of a transition metal” as used herein refers to a compound in which a transition metal and tellurium are ionically bonded, covalently bonded, and/or metallically bonded. Specifically, the telluride of the transition metal may include ZnTe, CoTe, or any combination thereof.

The term “telluride of a late transition metal” as used herein refers to a compound in which a late transition metal and tellurium are ionically bonded, covalently bonded, and/or metallically bonded. Specifically, the telluride of the late transition metal may include Bi₂Te₃.

The term “selenide of a lanthanoid metal” as used herein refers to a compound in which a lanthanoid metal and selenium (Se) are ionically bonded, covalently bonded, and/or metallically bonded. Specifically, the selenide of the lanthanoid metal may include EuSe, YbSe, SmSe, TmSe, or any combination thereof.

The term “selenide of a transition metal” as used herein refers to a compound in which a transition metal and selenium are ionically bonded, covalently bonded, and/or metallically bonded. Specifically, the selenide of the transition metal may include ZnSe, CoSe, or any combination thereof.

The term “selenide of a late transition metal” as used herein refers to a compound in which a late transition metal and selenium are ionically bonded, covalently bonded, and/or metallically bonded. Specifically, the selenide of the late transition metal may include Bi₂Se₃.

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the description, it will be understood that when an element (or region, layer, part, etc.) is referred to as being “on”, “adjacent to”, “connected to”, or “coupled to” another element, it can be directly on, adjacent to, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

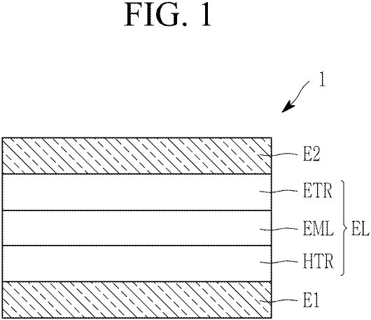

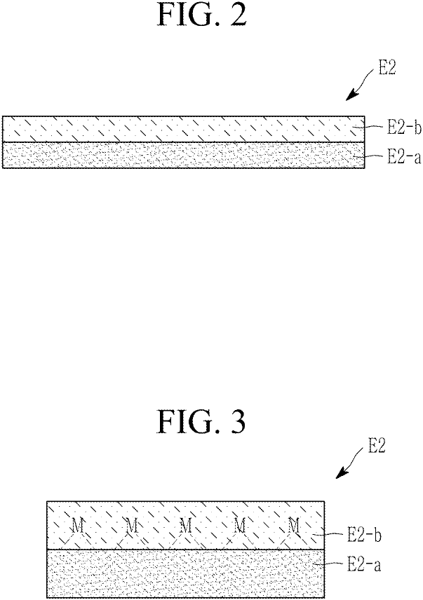

Hereinafter, a light emitting device according to an embodiment will be described with reference to FIG. 1 to FIG. 3. FIG. 1 illustrates a schematic cross-sectional view of a light emitting device according to an embodiment, and FIG. 2 and FIG. 3 respectively illustrate a schematic cross-sectional view of a second electrode according to an embodiment.

First, referring to FIG. 1, a light emitting device 1 may include a first electrode E1, a second electrode E2, and a light emitting unit (or a light emitting part) EL positioned between the first electrode E1 and the second electrode E2.

The light emitting device 1 according to the embodiment of the disclosure may be a top emission type. The first electrode E1 may be an anode, and the second electrode E2 may be a cathode. The light emitting device 1 according to another embodiment of the disclosure may be a bottom emission type. The first electrode E1 may be a cathode, and the second electrode E2 may be an anode. In the light emitting device 1 according to the embodiment of the disclosure, the first electrode E1 is a reflective electrode, and the second electrode E2 is a transmissive or transflective electrode, so the light emitting device 1 emits light from the first electrode E1 to the second electrode E2. Hereinafter, a case in which the light emitting device is a top emission type will be described.

The first electrode E1 may be formed, for example, by providing a material for the first electrode on a substrate by using a deposition method or a sputtering method. In case that the first electrode E1 is an anode, a material for the first electrode may be selected from materials having a high work function to facilitate hole injection.

The first electrode E1 may be a reflective electrode, a transflective electrode, or a transmissive electrode. In order to form the first electrode E1, which is a transmissive electrode, the material for the first electrode may be selected from an indium tin oxide (ITO), an indium zinc oxide (IZO), a tin oxide (SnO₂), a zinc oxide (ZnO), or a combination thereof, but is not limited thereto. As another example, in order to form the first electrode E1, which is a transflective electrode or a reflective electrode, the material for the first electrode may be selected from magnesium (Mg), silver (Ag), aluminum (Al), aluminum-lithium (Al—Li), calcium (Ca), magnesium-indium (Mg—In), magnesium-silver (Mg—Ag), or a combination thereof, but is not limited thereto.

The first electrode E1 may have a single-layered structure having a single layer, or a multi-layered structure having multiple layers. For example, the first electrode E1 may have a three-layered structure of ITO/Ag/ITO, but is not limited thereto.

The light emitting unit EL may be disposed on the first electrode E1. The embodiment including one light emitting unit EL is illustrated in the specification, but the embodiment is not limited thereto, and the light emitting device 1 according to the embodiment may include at least one or more light emitting units EL.

The light emitting unit EL may include an emission layer EML. The light emitting unit EL may include at least one of a hole transport region HTR and an electron transport region ETR. The hole transport region HTR may include a hole injection layer, a hole transport layer, an electron blocking layer, or a combination thereof. The electron transport region ETR may include a hole blocking layer, an electron transport layer, an electron injection layer, or a combination thereof.

The hole transport region HTR may be formed by using a general method. For example, the hole transport region HTR may be formed by using various methods such as a vacuum deposition method, a spin coating method, a casting method, a Langmuir-Blodgett (LB) method, an inkjet printing method, a laser printing method, a laser induced thermal imaging (LITI) method, and the like.

The hole injection layer included in the hole transport region HTR may include a hole injection material. The hole injection material may include a phthalocyanine compound such as copper phthalocyanine; DNTPD(N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris{N,-(2-naphthyl)-N-phenylamino}-triphenylamine), PEDOT/PSS (Poly(3,4-ethylenedioxythiophene)/ Poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPB (N,N′-di(naphthalene-1-yl)-N,N′-diphenyl-benzidine), NPD (N,N′-di(1-naphthyl)-N,N′-diphenyl-(1,1′-biphenyl)-4,4′-diamine), polyether ketone (TPAPEK) containing triphenylamine, 4-isopropyl-4′-methyldiphenyliodonium [tetrakis(pentafluorophenyl)borate], HAT-CN (dipyrazino[2,3-f: 2′,3′-h] quinoxaline-2,3,6,7,10,11-hexacarbonitrile), and the like.

The hole transport layer included in the hole transport region may include a hole transport material. The hole transport material may include carbazole derivatives such as N-phenylcarbazole and polyvinylcarbazole, fluorene-based derivatives, TPD (N,N′-bis(3-methylphenyl)-N,N′-diphenyl-[1,1-biphenyl]-4,4′-diamine), TCTA (4,4′,4″-tris(N-carbazolyl) triphenylamine) such as triphenylamine derivatives, NPB (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), CzSi (9-(4-tert-butylphenyl)-3,6-bis(triphenylsilyl)-9H-carbazole), m-MTDATA (4,4′,4″-[tris(3-methylphenyl)phenylamino] triphenylamine), and the like.

A thickness of the hole transport region HTR may be about 100 Å to about 10,000 Å, for example, about 100 Å to about 5000 Å. A thickness of the hole injection layer may be, for example, about 30 Å to about 1000 Å, and a thickness of the hole transport layer may be about 30 Å to about 1000 Å. In case that the thicknesses of the hole transport region HTR, the hole injection layer, and the hole transport layer satisfies the above-mentioned ranges, a satisfactory hole transport characteristic may be obtained without a substantial increase in driving voltage.

The electron blocking layer may be a layer that prevents electrons from leaking from the electron transport region ETR to the hole transport region HTR. A thickness of the electron blocking layer may be about 10 Å to about 1000 Å. The electron blocking layer may include, for example, carbazole derivatives such as N-phenylcarbazole and polyvinylcarbazole, fluorene derivatives, triphenylamine derivatives such as TPD (N,N′-bis(3-methylphenyl)-N,N′-diphenyl-[1,1-biphenyl]-4,4′-diamine) and TCTA (4,4′,4″-tris(N-carbazolyl) triphenylamine), NPD (N,N′-di(naphthalene-l-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), or mCP.

The hole transport region HTR may also include a charge generating material for conductive improvement in addition to the above-mentioned materials. The charge generating material may be uniformly or non-uniformly dispersed in the hole transport region HTR. The charge generating material may be, for example, a p-dopant. The p-dopant may be one of a quinone derivative, a metal oxide, and a cyano group-containing compound, but is not limited thereto. For example, non-limiting examples of p-dopants may include quinone derivatives such as TCNQ (tetracyanoquinodimethane) and F4-TCNQ (2,3,5,6-tetrafluoro-7,7′,8,8′-tetracyanoquinodimethane), and metal oxides such as tungsten oxide and molybdenum oxide, but are not limited thereto.

Each layer of the electron transport region ETR may be formed by using general methods. For example, the electron transport region ETR may be formed by using various methods such as a vacuum deposition method, a spin coating method, a casting method, a Langmuir-Blodgett (LB) method, an inkjet printing method, a laser printing method, a laser induced thermal imaging (LITI) method, and the like.

The electron injection layer included in the electron transport region ETR may include an electron injection material. As the electron injection material, a metal halide such as LiF, NaCl, CsF, RbCl, and RbI, a lanthanide metal such as Yb, a metal oxide such as Li₂O and BaO, or a lithium quinolate (LiQ) may be used, but the embodiment is not limited thereto. The electron injection layer may also be made of a material in which an electron transport material and an insulating organo metal salt are mixed. The organo metal salt may be a material having an energy band gap of about 4 eV or more. Specifically, for example, the organo metal salt may include a metal acetate, a metal benzoate, a metal acetoacetate, a metal acetylacetonate, or a metal stearate.

The electron transport layer included in the electron transport region ETR may include an electron transport material. The electron transport material may include a triazine-based compound or an anthracene-based compound. However, the embodiment is not limited thereto, and the electron transport material may include, for example, Alq₃(tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalene-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,08)-(1,1′-biphenyl-4-olato)aluminum), Bebq₂ (beryllium bis(benzoquinolin-10-olate), and (9,10-di(naphthalene-2-yl)anthracene), TSPO1 (diphenyl(4-(triphenylsilyl)phenyl)phosphine oxide), TPM-TAZ (2,4,6-tris(3-(pyrimidin-5-yl)phenyl)-1,3,5-triazine), and a mixture thereof.

Each of the electron injection layers may have a thickness of about 1 Å to about 500 Å, or about 3 Å to about 300 Å. In case that the thickness of the electron injection layer satisfies the range as described above, a satisfactory electron injection characteristic may be obtained without a substantial increase in driving voltage.

Each of the electron transport layers may have a thickness of about 100 Å to about 1000 Å, for example, about 150 Å to about 500 Å. In case that the thickness of the electron transport layer satisfies the range as described above, a satisfactory electron transport characteristic may be obtained without a substantial increase in driving voltage.

The hole blocking layer may be a layer that prevents holes from leaking from the hole transport region HTR to the electron transport region ETR. A thickness of the hole blocking layer may be about 10 Å to about 1000 Å. The hole blocking layer may include, for example, at least one of BCP (2,9-dimethyl-4,7-diphenyl-1,10-phenanthroline), Bphen (4,7-diphenyl-1,10-phenanthroline), and T2T (2,4,6-tri([1,1′-biphenyl]-3-yl)-1,3,5-triazine), but is not limited thereto.

The emission layer EML may include at least one of an organic compound and a semiconductor compound, but is not limited thereto. In case that the emission layer EML contains an organic compound, the light emitting device may be referred to as an organic light emitting device.

The organic compound may include a host and a dopant. The semiconductor compound may be a quantum dot, for example, the light emitting device may be a quantum dot light emitting device. As another example, the semiconductor compound may be an organic and/or inorganic perovskite.

A thickness of the emission layer EML may be about 0.1 nm to about 100 nm. Specifically, the thickness of the emission layer EML may be about 15 nm to about 50 nm. More specifically, in case that the emission layer EML emits blue light, a thickness of the blue emission layer may be about 15 nm to about 20 nm, and in case that the emission layer emits green light, a thickness of the green emission layer may be about 20 nm to about 40 nm, while in case that the emission layer emits red light, a thickness of the red emission layer may be about 40 nm to about 50 nm. In case that the above-mentioned range is satisfied, the light emitting device may provide an excellent light emitting characteristic without a substantial increase in driving voltage.

The emission layer EML may include a host material and a dopant material. The emission layer EML may be formed by using a phosphorescent or fluorescent light emitting material as a dopant in a host material. The emission layer EML may be formed by including a thermally activated delayed fluorescence (TADF) dopant in a host material. As another example, the emission layer EML may include a quantum dot material as a light emitting material. A core of the quantum dot may be selected from a group of II-VI compound, a group III-V compound, a group IV-VI compound, a group IV element, a group IV compound, or a combination thereof.

A color of light emitted from the emission layer EML may be determined by a combination of a host material and a dopant material, or a type of quantum dot material and a size of a core.

As the host material of the emission layer EML, although not particularly limited, it may be selected from a fluoranthene derivative, a pyrene derivative, an arylacetylene derivative, an anthracene derivative, a fluorene derivative, a perylene derivative, a chrysene derivative, and the like. The pyrene derivative, the perylene derivative, and anthracene derivative may be selected.

As the dopant material of the emission layer EML, although not particularly limited, it may include styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), perylene and its derivatives (for example, 2,5,8,11-tetra-t-butylperylene (TBP)), pyrene and its derivatives (for example, 1,1-dipyrene, 1,4-dipyrenylbenzene, 1,4-bis(N,N-diphenylamino)pyrene), or N1,N6-di(naphthalen-2-yl)-N1,N6-diphenylpyrene-1,6-diamine).

A thickness of the second electrode E2 may be about 5 nm to about 20 nm. In case that the above-described range is satisfied, light absorption at the second electrode may be minimized, and a satisfactory electron injection characteristic may be obtained without a substantial increase in driving voltage.

The second electrode E2 may have a multi-layered structure having multiple layers. Hereinafter, a detailed structure of the second electrode E2 according to the embodiment will be described with reference to FIG. 2 and FIG. 3.

Referring to FIG. 2 and FIG. 3, the second electrode E2 according to the embodiment may include a first layer E2-a and a metal thin film layer E2-b. The first layer E2-a may be positioned adjacent to the light emitting unit EL, and the metal thin film layer E2-b may be positioned on the first layer E2-a. In the specification, the embodiment in which the second electrode E2 includes the first layer E2-a is illustrated and described, but the disclosure is not limited thereto, and a layer corresponding to the characteristic and material of the first layer E2-a may be included in the light emitting unit EL, in particular, in the electron transport region ETR, or may be positioned between the light emitting unit EL and the second electrode E2.

The first layer E2-a may include a first organic material. The first organic material may be coordinate-bonded with a metal included in the metal thin film layer E2-b, which will be described later. The first organic material according to the embodiment may include any material capable of being coordinate-bonded with a metal of the metal thin film layer E2-b, and may include, for example, a phenanthroline group, a pyrene group, a furan group, or a thiol group.

The first layer E2-a according to the embodiment may further include a first metal. The first metal may include at least one of Yb, Li, Cu, Ag, Au, Al, and Mg.

A thickness of the first layer E2-a according to the embodiment may be about 10 angstroms to about 100 angstroms. In case that the thickness of the first layer E2-a exceeds about 100 angstroms, a thickness of the second electrode E2 may become excessively thick, and in case that the thickness of the first layer E2-a is less than about 10 angstroms, it may not be easy to form the metal thin film layer E2-b on the first layer E2-a.

The metal thin film layer E2-b may include at least one type of metal. For example, the metal thin film layer E2-b may include a metal having electrical conductivity of about 1x10⁷ S/m or more. For example, the metal thin film layer E2-b may include one of Ag, Au, Cu, Al, and Mg.

The first layer E2-a according to the embodiment may include an organic compound including a coordination bonding site (A) as shown in Formula 1:

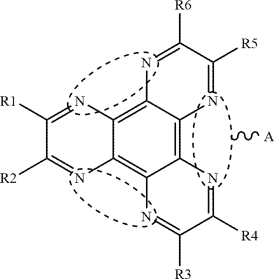

In Chemical Formula 1, R1, R2, R3, R3, R5, and R6 may be each independently hydrogen, deuterium, a halogen, an amine group, an epoxy group, a cyclohexyl epoxy group, an acryl group, a methacryl group, a thiol group, an isocyanate group, a nitrile group, a nitro group, a substituted or unsubstituted C₁-C₆₀ alkyl group, a substituted or unsubstituted C₂-C₆₀ alkenyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₁-C₆₀ heteroaryl group, a substituted or unsubstituted C₇-C₁₂ aralkyl group, a substituted or unsubstituted C₆-C₆₀ aryloxy group, or a substituted or unsubstituted C₆-C₆₀ arylthio group, but is not limited thereto. For example, Chemical Formula 1 may be represented as Chemical Formula 1-1, but is not limited thereto:

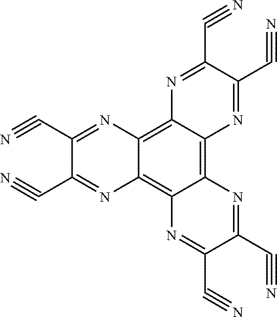 [SMILES: N#Cc1nc2c3nc(C#N)c(C#N)nc3c3nc(C#N)c(C#N)nc3c2nc1C#N]

As shown in FIG. 3, a coordination bond may be formed with a metal (M) included in the metal thin film layer E2-b at the coordination bonding site (A) included in the first layer E2-a. In forming the metal thin film layer E2-b on the first layer E2-a, the coordination bonding site (A as shown in the Chemical Formula 1) of the first layer E2-a may induce bonding with the metal atom (M) of the metal thin film layer E2-b. Accordingly, it may be possible to form a metal thin film layer E2-b having a stable film quality and a thin thickness on the first layer E2-a. For example, the metal thin film layer E2-b may be formed with a uniform film quality including a single metal, and it may have characteristics of high transmittance and conductivity.

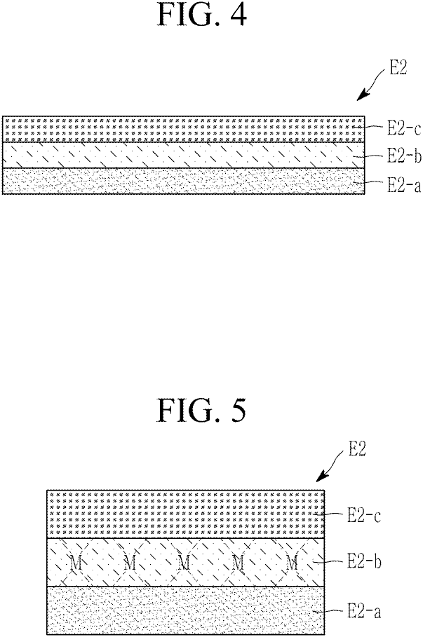

Hereinafter, a light emitting device according to an embodiment will be described with reference to FIG. 4 to FIG. 6. FIG. 4, FIG. 5, and FIG. 6 respectively illustrate a schematic cross-sectional view of a second electrode according to an embodiment. A description of the same constituent element as that described above will be omitted.

Referring to FIG. 4 and FIG. 5, the second electrode E2 according to the embodiment may include a first layer E2-a, a metal thin film layer E2-b, and a holding layer E2-c. The first layer E2-a may be positioned adjacent to the light emitting unit EL, and the metal thin film layer E2-b may be positioned on the first layer E2-a. The holding layer E2-c may be positioned on the metal thin film layer E2-b. The metal thin film layer E2-b may be positioned between the holding layer E2-c and the first layer E2-a.

In the disclosure, the embodiment in which the second electrode E2 includes the first layer E2-a, the metal thin film layer E2-b, and the holding layer E2-c is illustrated and described, but the embodiment is not limited thereto, and an embodiment in which the first layer E2-a is included in the light emitting unit EL, particularly, in the electron transport region ETR, and the holding layer E2-c is included in an encapsulation layer positioned on the light emitting device, may be possible.

The first layer E2-a and the holding layer E2-c may each independently include an organic material. The first layer E2-a may include a first organic material, and the holding layer E2-c may include a second organic material. Each of the first organic material and the second organic material may be coordinate-bonded with a metal included in the metal thin film layer E2-b, which will be described later. Each of the first organic material and the second organic material according to the embodiment may include any material capable of forming a coordination bond with the metal included in the metal thin film layer E2-b, and for example, may independently include a phenanthroline group, a pyrene group, a furan group, or a thiol group.

The first layer E2-a may further include a first metal doped into the first organic material. The holding layer E2-c may further include a second metal doped into the second organic material. The first metal and the second metal may each independently include at least one of Yb, Li, Cu, Ag, Au, Al, and Mg.

A thickness of the first layer E2-a according to the embodiment may be about 10 angstroms to about 100 angstroms. In case that the thickness of the first layer E2-a exceeds about 100 angstroms, a thickness of the second electrode E2 may become excessively thick, and in case that the thickness of the first layer E2-a is less than about 10 angstroms, it may not be easy to form a metal thin film layer E2-b on the first layer E2-a.

A thickness of the holding layer E2-c according to the embodiment may be about 10 angstroms to about 700 angstroms. In embodiments, the holding layer E2-c may have a thickness of about 10 angstroms to about 50 angstroms, or a thickness of about 400 angstroms to about 700 angstroms. In case that the thickness of the holding layer E2-c is about 10 angstroms to about 50 angstroms, the display device according to the embodiment may further include an auxiliary holding layer positioned on the holding layer E2-c.

The auxiliary holding layer may include, for example, α-NPD, NPB, TPD, m-MTDATA, Alq3, CuPc, TPD15 (N4,N4,N4′,N4′-tetra(biphenyl-4-yl)biphenyl-4,4′-diamine), TCTA (4,4′,4″-tris(N-carbazolyl)triphenylamine), or N,N′-bis(naphthalen-1-yl). The auxiliary holding layer may serve to efficiently emit light emitted from the emission layer EML of the light emitting device to the outside of the light emitting device. In case that the light emitting device of the embodiment further includes a thin film encapsulation layer, the auxiliary holding layer may be disposed between the second electrode E2 and the thin film encapsulation layer.

The metal thin film layer E2-b may include at least one type of metal. For example, the metal thin film layer E2-b may include a metal having electrical conductivity of about 1x10⁷ S/m or more. For example, the metal thin film layer E2-b may include one of Ag, Au, Cu, Al, and Mg.

The first layer E2-a and the holding layer E2-c according to the embodiment may include a first organic material and a second organic material including the coordination bonding site (A) as shown in Chemical Formula 1:

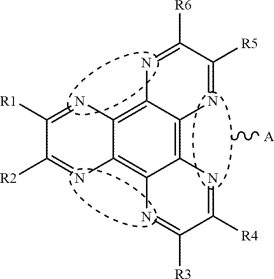

The coordination bonding site (A) included in the first organic material and the second organic material may form a coordination bond with the metal (M) included in the metal thin film layer E2-b as shown in FIG. 5. In forming the metal thin film layer E2-b, the first organic material of the first layer E2-a and the second organic material of the holding layer E2-c may induce bonding with the metal (M) of the metal thin film layer E2-b. Accordingly, the metal thin film layer E2-b may be formed to have a stable film quality and a thin thickness on the first layer E2-a. The metal thin film layer E2-b may be formed with uniform film quality including a single metal, and it may have characteristics of high transmittance and conductivity.

Referring to FIG. 6, the second electrode E2 according to the embodiment may further include an auxiliary layer E2-d positioned under the first layer E2-a. The auxiliary layer E2-d may have a higher electron affinity than the first layer E2-a. A lowest unoccupied molecular orbital (LUMO) energy level of the auxiliary layer E2-d according to the embodiment may be smaller than the LUMO energy level of the first layer E2-a. The auxiliary layer E2-d may include any organic or inorganic material that satisfies the condition, for example, HAT-CN, MoO₃, and the like.

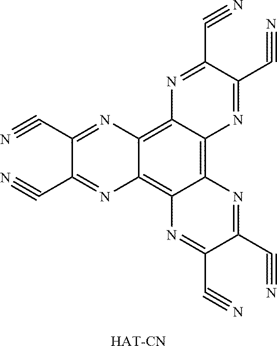

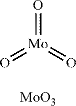

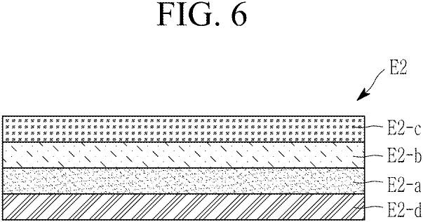

Hereinafter, a light emitting device according to an embodiment will be described with reference to FIG. 7. FIG. 7 illustrates a schematic cross-sectional view of a light emitting device according to an embodiment. A description of the same constituent elements as described above will be omitted.

Referring to FIG. 7, the light emitting device 1 may include m light emitting units EL. The light emitting device 1 according to the embodiment may include m-1 charge generating layers CGL1, CGL2, and CGL3 interposed between adjacent light emitting units EL. The light emitting device 1 according to the embodiment may include a first charge generating layer CGL1 positioned between a first light emitting unit EL1 and a second light emitting unit EL2, a second charge generating layer CGL2 positioned between the second light emitting unit EL2 and a third light emitting unit EL3, and a third charge generating layer CGL3 positioned between the third light emitting unit EL3 and a fourth light emitting unit EL4. Although the specification shows the embodiment including three charge generating layers CGL1, CGL2, and CGL3, the disclosure is not limited thereto, and the number of charge generating layers may vary depending on the number of light emitting units EL.

Each of the charge generating layers CGL1, CGL2, and CGL3 may include n-type charge generating layers n-CGL1, n-CGL2, and n-CGL3 that provide electrons to the light emitting unit EL and p-type charge generating layers p-CGL1, p-CGL2, and p-CGL3 that provide holes to the light emitting unit EL. Although not shown, in embodiments, a buffer layer may be further disposed between the n-type charge generating layers n-CGL1, n-CGL2, and n-CGL3 and the p-type charge generating layers p-CGL1, p-CGL2, and p-CGL3.

The charge generating layers CGL1, CGL2, and CGL3 may generate charges (electrons and holes) by forming a complex through an oxidation-reduction reaction in case that a voltage is applied thereto. The charge generating layers CGL1, CGL2, and CGL3 may provide the generated charges to the light emitting units EL adjacent thereto. The charge generating layers CGL1, CGL2, and CGL3 may increase a current efficiency in the light emitting unit EL, and may serve to adjust balance of charges between the adjacent light emitting units EL.

The first charge generating layer CGL1 may include a (1-n)-th type charge generating layer n-CGL1 and a (1-p)-th type charge generating layer p-CGL1. The (1-n)-th type charge generating layer n-CGL1 may be positioned adjacent to the first light emitting unit EL1 that is positioned on the first electrode E1, and the (1-p)-th type charge generating layer p-CGL1 may be positioned adjacent to the second light emitting unit EL2. The second charge generating layer CGL2 may include a (2-n)-th type charge generating layer n-CGL2 and a (2-p)-th type charge generating layer p-CGL2. The (2-n)-th type charge generating layer n-CGL2 may be positioned adjacent to the second light emitting unit EL2, and the (2-p)-th type charge generating layer p-CGL2 may be positioned adjacent to the third light emitting unit EL3. The third charge generating layer CGL3 may include a (3-n)-th type charge generating layer n-CGL3 and a (3-p)-th type charge generating layer p-CGL3. The (3-n)-th type charge generating layer n-CGL3 may be positioned adjacent to the third light emitting unit EL3, and the (3-p)-th type charge generating layer p-CGL3 may be positioned adjacent to the fourth light emitting unit EL4.

The second electrode E2 may be disposed on the m-th light emitting unit EL. The second electrode E2 may be a cathode, which is an electron injection electrode. The second electrode E2 may be similar to the second electrode E2 described above with reference to FIG. 1 to FIG. 3, the second electrode E2 described with reference to FIG. 4 and FIG. 5, or the second electrode E2 described with reference to FIG. 6.

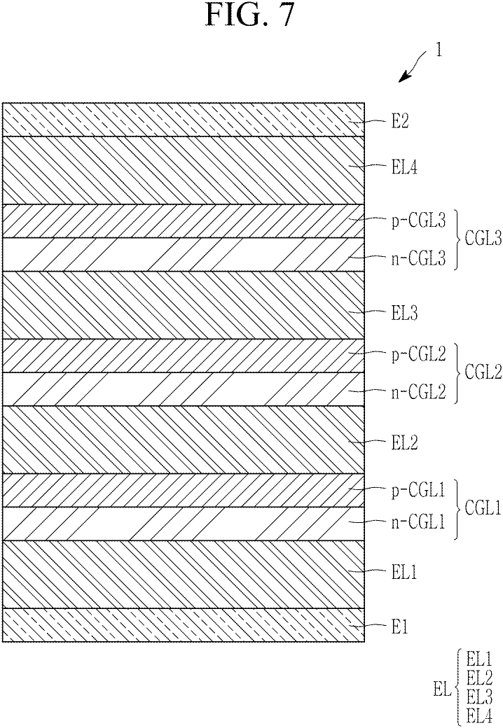

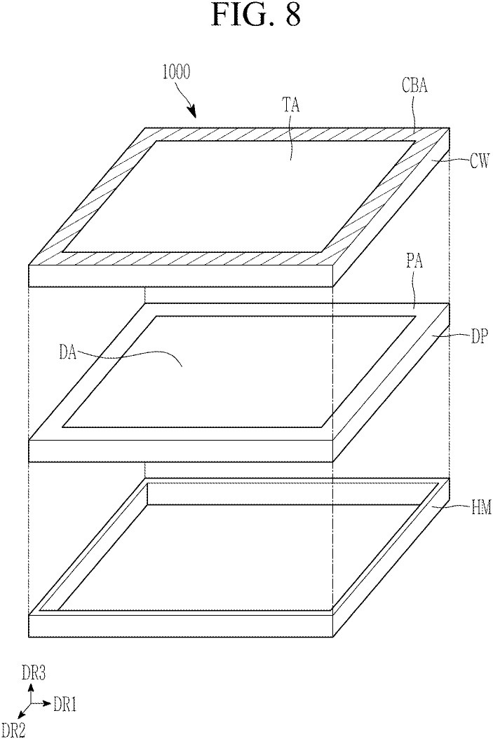

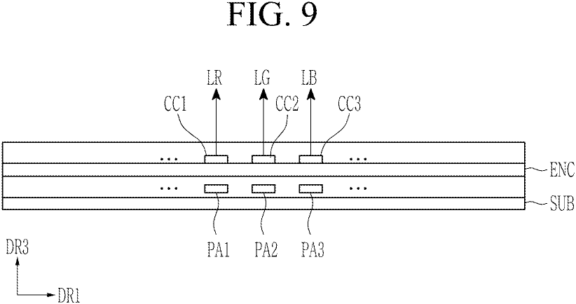

Hereinafter, a display device according to an embodiment will be described with reference to FIG. 8 to FIG. 10. FIG. 8 illustrates an exploded perspective view of a display device according to an embodiment, FIG. 9 illustrates a schematic cross-sectional view of a display panel according to an embodiment, and FIG. 10 illustrates a schematic cross-sectional view of a display panel according to an embodiment.

Referring to FIG. 8, the display device according to the embodiment may include a cover window CW, a display panel DP, and a housing HM.

The cover window CW may include an insulating panel. For example, the cover window CW may be made of glass, plastic, or a combination thereof.

A front surface of the cover window CW may define a front surface of a display device 1000. A transmission area TA may be an optically transparent area. For example, the transmission area TA may be an area having visible ray transmittance of about 90 % or more.

A blocking area CBA may define a shape of the transmission area TA. The blocking area CBA may be positioned adjacent to the transmission area TA, and may surround the transmission area TA. The blocking area CBA may be an area having relatively low light transmittance compared with the transmission area TA. The blocking area CBA may include an opaque material that blocks light. The blocking area CBA may have a color. The blocking area CBA may be defined by a bezel layer provided separately from a transparent substrate defining the transmission area TA, or may be defined by an ink layer formed by being inserted into or coloring the transparent substrate.

One surface of the display panel DP on which an image is displayed may be parallel to a plane defined by a first direction DR1 and a second direction DR2. A third direction DR3 may indicate a normal direction of the surface on which the image is displayed, for example, a thickness direction of the display panel DP. A front surface (or upper surface) and a back surface (or lower surface) of each member may be distinguished by the third direction DR3. However, directions indicated by the first to third directions DR1, DR2, and DR3 are relative concepts, and thus they may be changed into other directions.

The display panel DP may be a flat rigid display panel, but is not limited thereto, and may be a flexible display panel. The display panel DP may be formed of an organic light emitting display panel. However, the type of the display panel DP is not limited thereto, and the display panel may be formed as various types of panels. For example, the display panel DP may be formed as a liquid crystal panel, an electrophoretic display panel, an electrowetting display panel, or the like. The display panel DP may be formed as a next-generation display panel such as a micro light emitting diode display panel, a quantum dot light emitting diode display panel, or a quantum dot organic light emitting diode display panel.

The micro light emitting diode (Micro LED) display panel may be formed in such a way that the light emitting diode having a size of 10 to 100 micrometers constitutes each pixel. The micro light emitting diode display panel may have advantages in that an inorganic material may be used, a backlight may be omitted, it may have a fast reaction speed, it may output high brightness with low power, and it may not be broken in case of being bent. The quantum dot light emitting diode display panel may be formed by attaching a film including quantum dots or forming a material including quantum dots. The quantum dots may refer to particles that are made of inorganic materials such as indium or cadmium, may emit light by themselves, and may have a diameter of several nanometers or less. By controlling a particle size of the quantum dots, light of a desired color may be displayed. The quantum dot organic light emitting diode display panel may have a structure in which a blue organic light emitting diode is used as a light source, and a film including red and green quantum dots is attached thereon, or a material including red and green quantum dots is deposited to realize color. The display panel DP according to the embodiment may be configured as various other display panels.

As shown in FIG. 8, the display panel DP may include a display area DA in which an image is displayed, and a non-display area PA positioned adjacent to the display area DA. The non-display area PA may be an area in which no image is displayed. The display area DA may have, for example, a quadrangular shape, and the non-display area PA may have a shape surrounding the display area DA. However, the embodiment is not limited thereto, and the shapes of the display area DA and the non-display area PA may be relatively designed.

The housing HM may provide an inner space. The display panel DP may be mounted inside of the housing HM. In addition to the display panel DP, various electronic components, for example, a power supply part, a storage device, and an audio input/output module, may be mounted inside of the housing HM.

Hereinafter, a display panel according to an embodiment will be described with reference to FIG. 9. Referring to FIG. 9 together with FIG. 8, multiple pixels PA1, PA2, and PA3 may be formed on a substrate SUB corresponding to the display area DA of the display panel DP. Each of the pixels PA1, PA2, and PA3 may include multiple transistors and a light emitting device electrically connected thereto.

An encapsulation layer ENC may be positioned on the multiple pixels PA1, PA2, and PA3. The display area DA may be protected from external air or moisture by the encapsulation layer ENC. The encapsulation layer ENC may be integrally provided to overlap the entire display area DA, and may be partially disposed on the non-display area PA.

A first color conversion part CC1, a second color conversion part CC2, and a transmission part CC3 may be positioned on the encapsulation layer ENC. The first color conversion part CC1 may overlap the first pixel PA1, the second color conversion part CC2 may overlap the second pixel PA2, and the transmission part CC3 may overlap the third pixel PA3.

Light emitted from the first pixel PA1 may pass through the first color conversion part CC1 to provide red light (LR). Light emitted from the second pixel PA2 may pass through the second color conversion part CC2 to provide green light (LG). Light emitted from the third pixel PA3 may pass through the transmission part CC3 to provide blue light (LB).

Hereinafter, a stacked structure of respective pixels PA1, PA2, and PA3 and a stacked structure of the color conversion parts CC1 and CC2 and the transmission part CC3 will be described.

Referring to FIG. 10, a color conversion part CC may be positioned on a pixel part PP including the first to third pixels PA1, PA2, and PA3.

Referring to FIG. 10, the pixel part PP according to the embodiment may include the substrate SUB. The substrate SUB may include an inorganic insulating material such as glass or an organic insulating material such as a plastic such as polyimide (PI). The substrate SUB may be single-layered or multi-layered. The substrate SUB may have a structure in which at least one base layer and at least one inorganic layer, which include polymer resins sequentially stacked, are alternately stacked each other.

The substrate SUB may have various degrees of flexibility. The substrate SUB may be a rigid substrate, or a flexible substrate that is bendable, foldable, or rollable.

A buffer layer BF may be positioned on the substrate SUB. The buffer layer BF may block impurities from being transmitted from the substrate SUB to an upper layer of the buffer layer BF, particularly a semiconductor layer ACT, thereby preventing characteristic degradation of the semiconductor layer ACT and reducing stress. The buffer layer BF may include an inorganic insulating material such as a silicon nitride or a silicon oxide, or an organic insulating material. A portion or all of the buffer layer BF may be omitted.

The semiconductor layer ACT may be positioned on the buffer layer BF. The semiconductor layer ACT may include at least one of polycrystalline silicon and an oxide semiconductor. The semiconductor layer ACT may include a channel area (C), a first area (P), and a second area (Q). The first area (P) and the second area (Q) may be disposed at respective sides of the channel area (C). The channel area (C) may include a semiconductor with a small amount of impurity doped or a semiconductor with no impurity doped, and the first area (P) and the second area (Q) may include semiconductors with a large amount of impurity doped compared to the channel area (C). The semiconductor layer ACT may be formed of an oxide semiconductor, and a separate passivation layer (not shown) may be added to protect an oxide semiconductor material that is vulnerable to external environments such as a high temperature.

A first gate insulating layer GI1 may be positioned on the semiconductor layer ACT.

A gate electrode GE and a lower electrode LE may be positioned on the first gate insulating layer GI1. In embodiments, the gate electrode GE and the lower electrode LE may be integral with each other. The gate electrode GE and the lower electrode LE may be a single layer or a multilayer in which metal films containing one of copper (Cu), a copper alloy, aluminum (Al), an aluminum alloy, molybdenum (Mo), a molybdenum alloy, titanium (Ti), and a titanium alloy are stacked each other. The gate electrode GE may overlap the channel area (C) of the semiconductor layer ACT.

A second gate insulating layer GI2 may be positioned on the gate electrode GE and the first gate insulating layer GI1. The first gate insulating layer GI1 and the second gate insulating layer GI2 may be a single layer or multilayer including at least one of a silicon oxide (SiOₓ), a silicon nitride (SiNₓ), and a silicon oxynitride (SiOₓN_{y}).

An upper electrode UE may be positioned on the second gate insulating layer GI2. The upper electrode UE may form a storage capacitor while overlapping the lower electrode LE.

A first interlayer insulating layer IL1 may be positioned on the upper electrode UE. The first interlayer insulating layer IL1 may be a single layer or multilayer including at least one of a silicon oxide (SiOₓ), a silicon nitride (SiNₓ), and a silicon oxynitride (SiOₓN_{y}).

A source electrode SE and a drain electrode DE may be positioned on the first interlayer insulating layer IL1. The source electrode SE and the drain electrode DE may be electrically connected to the first area (P) and the second area (Q) of the semiconductor layer ACT through a contact hole formed in the insulating layers, respectively.

The source electrode SE and the drain electrode DE may include aluminum (Al), silver (Ag), magnesium (Mg), gold (Au), nickel (Ni), chromium (Cr), calcium (Ca), molybdenum (Mo), titanium (Ti), tungsten (W), and/ or copper (Cu), and may have a single-layered or multi-layered structure including them.

A second interlayer insulating layer IL2 may be positioned on the first interlayer insulating layer IL1, the source electrode SE, and the drain electrode DE. The second interlayer insulating layer IL2 may include an organic insulating material such as a general purpose polymer such as poly(methylmethacrylate) (PMMA) or polystyrene (PS), a polymer derivative having a phenolic group, a acryl-based polymer, an imide-based polymer, a polyimide, an acryl-based polymer, or a siloxane-based polymer.

The first electrode E1 may be positioned on the second interlayer insulating layer IL2. The first electrode E1 may be electrically connected to the drain electrode DE through a contact hole formed in the second interlayer insulating layer IL2.

The first electrode E1 may include a metal such as silver (Ag), lithium (Li), calcium (Ca), aluminum (Al), magnesium (Mg), or gold (Au), and may also include a transparent conductive oxide (TCO) such as an indium tin oxide (ITO) or an indium zinc oxide (IZO). The first electrode E1 may be formed of a single layer including a metal material or a transparent conductive oxide, or a multilayer including them. For example, the first electrode E1 may have a triple-layered structure of indium tin oxide (ITO)/silver (Ag)/indium tin oxide (ITO).

A transistor consists of the gate electrode GE, the semiconductor layer ACT, the source electrode SE, and the drain electrode DE may be electrically connected to the first electrode E1 to supply a current to a light emitting device.

A partition wall or bank IL3 may be positioned on the second interlayer insulating layer IL2 and the first electrode E1. Although not shown, a spacer (not shown) may be positioned on the bank IL3. The bank IL3 may overlap at least a portion of the first electrode E1, and may have a bank opening defining a light emitting region.

The bank IL3 may include an organic insulating material such as a general purpose polymer such as poly(methylmethacrylate) (PMMA) or polystyrene (PS), a polymer derivative having a phenolic group, an acryl-based polymer, an imide-based polymer, a polyimide, an acryl-based polymer, or a siloxane-based polymer.

The light emitting unit EL and the second electrode E2 may be positioned on the bank IL3. The second electrode E2 may be similar to the second electrode described above with reference to FIG. 1 to FIG. 3, the second electrode described above with reference to FIG. 4 and FIG. 5, or the second electrode described above with reference to FIG. 6.

The first electrode E1, the emission unit EL, and the second electrode E2 may constitute a light emitting device. Here, the first electrode E1 may be an anode, which is a hole injection electrode, and the second electrode E2 may be a cathode, which is an electron injection electrode. However, the embodiment is not necessarily limited thereto, and a first electrode E1 may be a cathode and a second electrode E2 may be an anode, according to a driving method of the light emitting display device.

An encapsulation layer ENC may be positioned on the second electrode E2. The encapsulation layer ENC may cover and seal not only an upper surface but also a side surface of the light emitting device. Since the light emitting device is very vulnerable to moisture and oxygen, the encapsulation layer ENC may seal the light emitting device to block inflow of moisture and oxygen from the outside.

The encapsulation layer ENC may include multiple layers, and it may be formed as a composite film including both an inorganic layer and an organic layer, and for example, it may be formed as a triple layer in which a first encapsulation inorganic layer EIL1, an encapsulation organic layer EOL, and a second encapsulation inorganic layer EIL2 are sequentially formed.

The first encapsulation inorganic layer EIL1 may cover the second electrode E2. The first encapsulation inorganic layer EIL1 may prevent external moisture or oxygen from penetrating into the light emitting device. For example, the first encapsulation inorganic layer EIL1 may include a silicon nitride, a silicon oxide, a silicon oxynitride, or a combination thereof. The first encapsulation inorganic layer EIL1 may be formed by a deposition process.

The encapsulation organic layer EOL may be disposed on the first encapsulation inorganic layer EIL1 to contact the first encapsulation inorganic layer EIL1. Curved portions formed on an upper surface of the first encapsulation inorganic layer EIL1 or particles being present on the first encapsulation inorganic layer EIL1 may be covered by the encapsulation organic layer EOL, so that influence on constituent elements formed on the encapsulation organic layer EOL by the surface state of the upper surface of the first encapsulation inorganic layer EIL1 may be blocked. The encapsulation organic layer EOL may reduce stress between layers in contact with each other. The encapsulation organic layer EOL may include an organic material, and may be formed by a solution process such as a spin coating, slit coating, or inkjet process.

The second encapsulation inorganic layer EIL2 may be disposed on the encapsulation organic layer EOL to cover the encapsulation organic layer EOL. The second encapsulation inorganic layer EIL2 may be stably formed on a relatively flat surface compared to the first encapsulation inorganic layer EIL1. The second encapsulation inorganic layer EIL2 may encapsulate moisture discharged from the encapsulation organic layer EOL to prevent outflow to the outside. The second encapsulation inorganic layer EIL2 may include a silicon nitride, a silicon oxide, a silicon oxynitride, or a combination thereof. The second encapsulation inorganic layer EIL2 may be formed by a deposition process.

The color conversion part CC may be disposed on the encapsulation layer ENC.

The color conversion part CC may include a first insulating layer P1 positioned on the encapsulation layer ENC. The first insulating layer P1 may be integrally formed to overlap the entire display area. The first insulating layer P1 may be a single layer or multilayer including at least one of a silicon oxide (SiOₓ), a silicon nitride (SiNₓ), and a silicon oxynitride (SiOₓNy).

A first light blocking layer BM1 may be positioned on the first insulating layer P1. The first light blocking layer BM1 may define an area in which a first color conversion layer CCL1, a second color conversion layer CCL2, and a transmission layer CCL3 are positioned.

The first color conversion layer CCL1, the second color conversion layer CCL2, and the transmission layer CCL3 may be positioned in the area defined by the first light blocking layer BM1. The first color conversion layer CCL1, the second color conversion layer CCL2, and the transmission layer CCL3 may be formed by an inkjet process, but are not limited thereto, and may be formed by using any manufacturing method.

The transmission layer CCL3 may transmit light of a first wavelength incident from the light emitting device, and may include multiple scatterers SC. The light of the first wavelength may be blue light having a maximum light emitting peak wavelength of about 380 nm to about 480 nm, for example, about 420 nm or more, about 430 nm or more, about 440 nm or more, or about 445 nm or more, and about 470 nm or less, about 460 nm or less, or about 455 nm or less.

The first color conversion layer CCL1 may color-convert light of the first wavelength incident from the light emitting device into red light, and may include multiple scatterers SC and multiple first quantum dots SN1. The red light may have a maximum light emitting peak wavelength of about 600 nm to about 650 nm, for example, about 620 nm to about 650 nm.

The second color conversion layer CCL2 may color-convert light of the first wavelength incident from the light emitting device into green light, and may include multiple scatterers SC and multiple second quantum dots SN2. The green light may have a maximum light emitting peak wavelength of about 500 nm to about 550 nm, for example, about 510 nm to about 550 nm.

The multiple scatterers SC may scatter light incident on the first color conversion layer CCL1, the second color conversion layer CCL2, and the transmission layer CCL3 to increase light efficiency.

Each of the first quantum dot SN1 and the second quantum dot SN2 (hereinafter, also referred to as semiconductor nanocrystal) may independently include a Group II-VI compound, a Group III-V compound, a Group IV-VI compound, a Group IV element or compound, a Group I-III-VI compound, a Group II-III-VI compound, a Group I-II-IV-VI compound, or a combination thereof. The quantum dot may not include cadmium.

The Group II-VI compound may be a binary element compound selected from CdSe, CdTe, ZnS, ZnSe, ZnTe, ZnO, HgS, HgSe, HgTe, MgSe, MgS, and a mixture thereof; a ternary element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; or a quaternary element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI compound may further include a Group III metal.

The Group III-V compound may be a binary element compound selected from GaN, GaP, GaAs, GaSb, AlN, AlP, AlAs, AlSb, InN, InP, InAs, InSb, and a mixture thereof; a ternary element compound selected from GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof; or a quaternary element compound selected from GaAlNP, GaA1NAs, GaA1NSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The Group III-V compound may further include a Group II metal (for example, InZnP).

The Group IV-VI compound may be a binary element compound selected from SnS, SnSe, SnTe, PbS, PbSe, PbTe, and a mixture thereof; a ternary element compound selected from SnSeS, SnSeTe, SnSTe, PbSeS, PbSeTe, PbSTe, SnPbS, SnPbSe, SnPbTe, and a mixture thereof; or a quaternary element compound selected from SnPbSSe, SnPbSeTe, SnPbSTe, and a mixture thereof.

The Group IV element or compound may be a singular element compound selected from Si, Ge, or a combination thereof, or a binary element compound selected from SiC, SiGe, or a combination thereof, but is not limited thereto.

The Group I-III-VI compound may include, for example, CuInSe₂, CuInS₂, CuInGaSe, and CuInGaS, but is not limited thereto. The Group I-II-IV-VI compound may include, for example, CuZnSnSe and CuZnSnS, but is not limited thereto. The Group IV element or compound may be a singular element selected from Si, Ge, and a mixture thereof, or a binary element compound selected from SiC, SiGe, and a mixture thereof.

The Group II-III-VI compounds may be selected from ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, or a combination thereof, but are not limited thereto.

The Group I-II-IV-VI compound may be selected from CuZnSnSe and CuZnSnS, but is not limited thereto.

In the embodiment, the quantum dot may not include cadmium. The quantum dot may include a semiconductor nanocrystal based on a Group III-V compound including indium and phosphorus. The Group III-V compound may further include zinc. The quantum dot may include a semiconductor nanocrystal based on a Group II-VI compound including a chalcogen element (for example, sulfur, selenium, tellurium, or a combination thereof) and zinc.

In the quantum dot, the binary element compound, the ternary element compound, and/or the quaternary element compound, which are described above, may be present in particles at uniform concentrations, or they may be divided into states having partially different concentrations to be present in the same particle, respectively. A core/shell structure in which some quantum dots enclose some other quantum dots may be possible. An interface between the core and the shell may have a concentration gradient in which a concentration of elements of the shell decreases closer to its center.

In embodiments, the quantum dot may have a core-shell structure that includes a core including the nanocrystal described above and a shell surrounding the core. The shell of the quantum dot may serve as a passivation layer for maintaining a semiconductor characteristic and/or as a charging layer for applying an electrophoretic characteristic to the quantum dot by preventing chemical denaturation of the core. The shell may be a single layer or a multilayer. An interface between the core and the shell may have a concentration gradient in which a concentration of elements of the shell decreases closer to its center. An example of the shell of the quantum dot may include a metal or nonmetal oxide, a semiconductor compound, or a combination thereof.

For example, the metal or non-metal oxide may be a binary element compound such as SiO₂, Al₂O₃, TiO₂, ZnO, MnO, Mn₂O₃, Mn₃O_{4,} CuO, FeO, Fe₂O₃, Fe₃O₄, CoO, Co₃O₄, NiO, and the like, or a ternary element compound such as MgAl₂O₄, CoFe₂O₄, NiFe₂O₄, CoMn₂O₄, and the like, but the embodiments are not limited thereto.

The semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the embodiments are not limited thereto.

An interface between the core and the shell may have a concentration gradient in which a concentration of elements of the shell decreases closer to its center. The semiconductor nanocrystal may have a structure including one semiconductor nanocrystal core and a multi-layered shell surrounding the semiconductor nanocrystal core. In the embodiment, the multi-layered shell may have two or more layers, for example, two, three, four, five, or more layers. Two adjacent layers of the shell may have a single composition or different compositions. In the multi-layered shell, each layer may have a composition that varies along a radius.

The quantum dot may have a full width at half maximum (FWHM) of the light-emitting wavelength spectrum that is equal to or less than about 45 nm, equal to or less than about 40 nm, or equal to or less than about 30 nm, and in this range, color purity or color reproducibility may be improved. Since light emitted through the quantum dot is emitted in all directions, a viewing angle of light may be improved.

In the quantum dot, the shell material and the core material may have different energy bandgap. For example, the energy bandgap of the shell material may be greater than that of the core material. In another embodiment, the energy bandgap of the shell material may be smaller than that of the core material. The quantum dot may have a multi-layered shell. In the multi-layered shell, an energy bandgap of an outer layer thereof may be larger than that of an inner layer thereof (for example, a layer closer to the core). In the multi-layered shell, the energy bandgap of the outer layer may be smaller than the energy bandgap of the inner layer.

The quantum dot may adjust an absorption/emission wavelength by adjusting a composition and size thereof. The maximum emission peak wavelength of the quantum dot may have a wavelength range from ultraviolet to infrared wavelengths or more.

The quantum dot may include an organic ligand (for example, having a hydrophobic moiety and/or a hydrophilic moiety). The organic ligand moiety may be bound to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein R is independently a C3 to C40 substituted or unsubstituted aliphatic hydrocarbon group such as a C3 to C40 (for example, C5 or greater and C24 or less) substituted or unsubstituted alkyl, or a substituted or unsubstituted alkenyl, a C6 to C40 (for example, C6 or greater and C20 or less) substituted or unsubstituted aromatic hydrocarbon group such as a substituted or unsubstituted C6 to C40 aryl group, or a combination thereof.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octylphosphine, dioctyl phosphine, tributylphosphine, or trioctylphosphine; a phosphine compound or an oxide compound thereof such methyl phosphine oxide, ethyl phosphine oxide, propyl phosphine oxide, butyl phosphine oxide pentyl phosphine oxide, tributylphosphine oxide, octylphosphine oxide, dioctyl phosphine oxide, or trioctylphosphine oxide; a diphenyl phosphine, triphenyl phosphine compound, or an oxide compound thereof; a C5 to C20 alkyl phosphonic acid such as hexylphosphinic acid, octylphosphinic acid, dodecanephosphinic acid, tetradecanephosphinic acid, hexadecanephosphinic acid, octadecanephosphinic acid; and the like, but are not limited thereto. The quantum dot may include a hydrophobic organic ligand alone or in a mixture of at least one type. The hydrophobic organic ligand may not include a photopolymerizable moiety (for example, an acrylate group, a methacrylate group, etc.).

A second insulating layer P2 may be positioned on the first color conversion layer CCL1, the second color conversion layer CCL2, and the transmission layer CCL3. The second insulating layer P2 may cover and may protect the first color conversion layer CCL1, the second color conversion layer CCL2, and the transmission layer CCL3, so that it is possible to prevent foreign particles from flowing into the first color conversion layer CCL1, the second color conversion layer CCL2, and the transmission layer CCL3. The second insulating layer P2 may be a single layer or multilayer, and may be formed as a multilayer having different refractive indices.

A first color filter CF1, a second color filter CF2, and a third color filter CF3 may be positioned on the second insulating layer P2.

The first color filter CF1 may transmit red light that has passed through the first color conversion layer CCL1, and may absorb light of the other wavelength, thereby increasing purity of red light emitted to the outside of the display device. The second color filter CF2 may transmit green light that has passed through the second color conversion layer CCL2, and may absorb light of the other wavelength, thereby increasing purity of green light emitted to the outside of the display device. The third color filter CF3 may transmit blue light that has passed through the transmission layer CCL3, and may absorb light of the other wavelength, thereby increasing purity of blue light emitted to the outside of the display device.

A second light blocking layer BM2 may be positioned between the first color filter CF1, the second color filter CF2, and the third color filter CF3. The second light blocking layer BM2 may include a light blocking material, or may have a shape in which at least two or more of the first color filter CF1, the second color filter CF2, and the third color filter CF3 overlap.

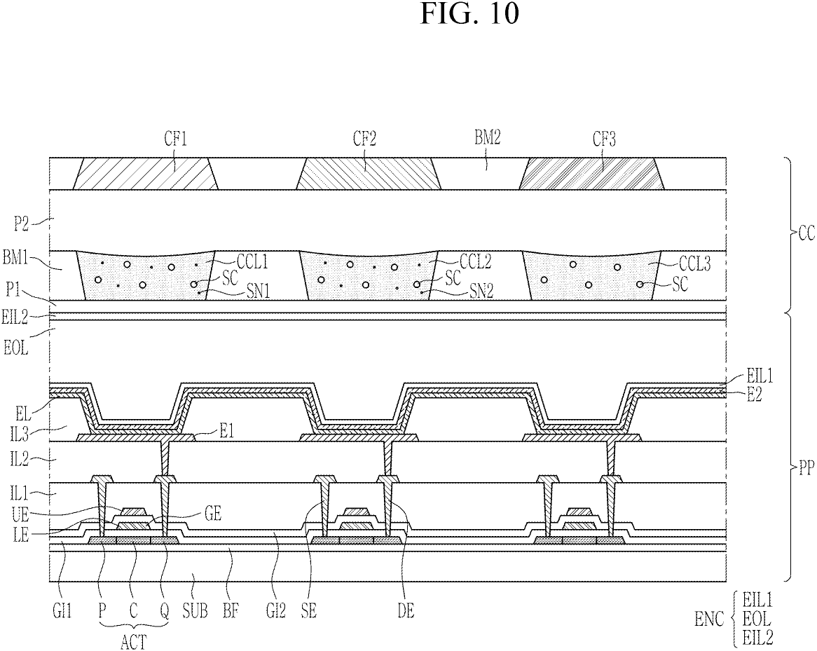

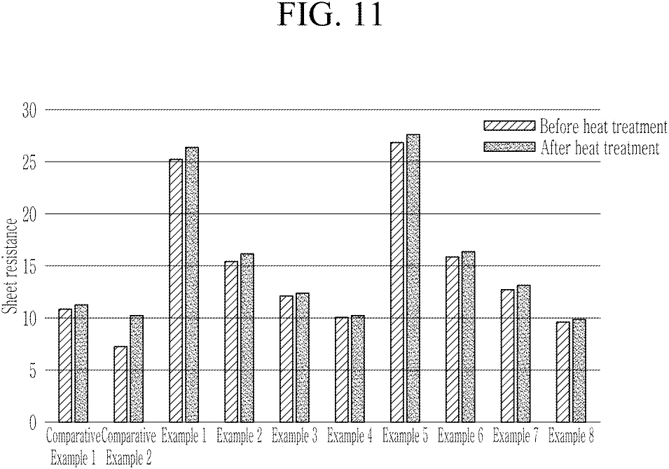

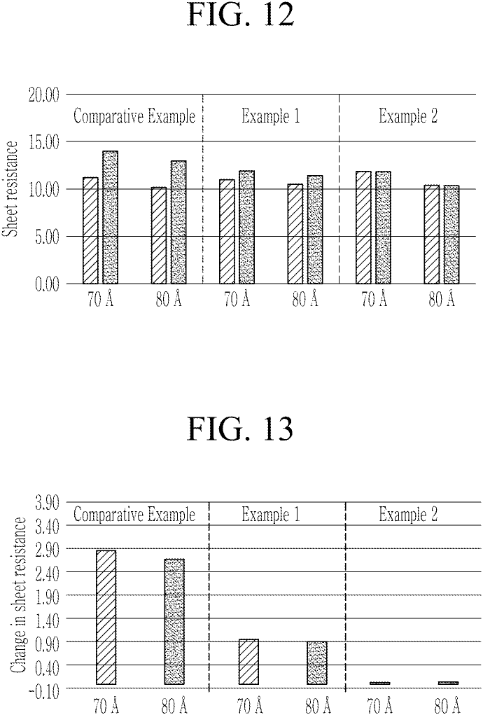

Hereinafter, characteristics of the second electrodes according to a comparative example and an example will be described with reference to FIG. 11 to FIG. 13. FIG. 11 illustrates a graph of sheet resistance of second electrodes according to a comparative example and an example, FIG. 12 illustrates a graph of sheet resistance of second electrodes according to a comparative example and an example, and FIG. 13 illustrates a graph of an amount of change in sheet resistance of second electrodes according to a comparative example and an example.

FIG. 11 and Table 1 show sheet resistance of the second electrodes according to Comparative Example 1, Comparative Example 2, and Example 1 to Example 8 before and after a heat treatment process.

The second electrode in Comparative Example 1 may include two types of metal (AgMg) formed on the electron transport region (Yb), and the second electrode in Comparative Example 2 may include one type of metal (Ag) formed on the electron transport region (Yb). The second electrode in Example 1 to Example 4 may include a first layer including HAT-CN, and a metal thin film layer including a single metal Ag. The second electrode in Example 5 to Example 8 may include a first layer including HAT-CN, a metal thin film layer including a single metal Ag, and a holding layer including HAT-CN.

Since the second electrode in Comparative Example 1 includes two types of metal (AgMg), it can be seen that the amount of change in sheet resistance before and after heat treatment is small, and the film quality is stably formed. However, the second electrode in Comparative Example 1 may have a lower characteristic than Comparative Example 2 including a single metal in terms of transmittance or conductivity.

In Comparative Example 2, it can be seen that the sheet resistance of the second electrode including a single metal is changed by about 3 ohm/sq by the heat treatment process. As in Comparative Example 2, it can be seen that in case that a single metal layer is formed on the electron transport region including the metal material, the stability of the corresponding metal layer is significantly reduced.

In the case of Example 1 to Example 4, it can be seen that, by providing the second electrode including the first layer including the organic material, even though they include a metal thin film layer including a single metal, the change in sheet resistance before and after the heat treatment is not large.

In the case of Example 5 to Example 8, it can be seen that, by providing the second electrode including the first layer and the holding layer, even though they include a metal thin film layer including a single metal, the change in sheet resistance before and after the heat treatment is not large.

The fact that the change in sheet resistance is not large may mean that, in Example 1 to Example 8, the metal thin film layer is stably formed on the first layer or the holding layer.

TABLE 1

| | Before heat treatment | | After heat treatment | |
|---|---|---|---|---|
| | Condition | Average (ohm/sq) | Average (ohm/ sq) | Changed amount (ohm/ sq) |
| Comparative Example 1 | Yb 10 A/AgMg 100 Å | 10.9 | 11.3 | 0.4 |
| Comparative Example 2 | Yb 10 Å/Ag 100 Å | 7.2 | 10.2 | 3.0 |
| Example 1 | HAT-CN 50 Å/Ag 70 Å | 25.3 | 26.4 | 1.1 |
| Example 2 | HAT-CN 50 Å/Ag 80 Å | 15.5 | 16.1 | 0.6 |
| Example 3 | HAT-CN 50 Å/Ag 90 Å | 12.1 | 12.4 | 0.3 |
| Example 4 | HAT-CN 50 Å/Ag 100 Å | 10.0 | 10.2 | 0.2 |
| Example 5 | HAT-CN 50 Å/Ag 70 Å/HAT-CN 10 Å | 26.9 | 27.7 | 0.8 |
| Example 6 | HAT-CN 50 Å/Ag 80 Å/HAT-CN 10 Å | 15.9 | 16.4 | 0.5 |
| Example 7 | HAT-CN 50 Å/Ag 90 Å/HAT-CN 10 Å | 12.8 | 13.1 | 0.3 |
| Example 8 | HAT-CN 50 Å/Ag 100 Å/HAT-CN 10 Å | 9.6 | 9.9 | 0.3 |

As shown in Table 2, in the case of the example including the first layer and the holding layer, compared with the Comparative Examples, it may be confirmed that the driving voltage is decreased to about 93 %, the luminous efficiency is increased to 105 %, and the lifespan of the light emitting device is increased to 105 %.

TABLE 2

| | Driving voltage | Efficiency | Lifespan |
|---|---|---|---|
| Comparative example (Yb/AgMg (9.5:0.5) | 100 % | 100 % | 100 % |
| Example (HAT-CN 50 Å/Ag 100 Å/ HAT-CN 10 Å) | 93 % | 105 % | 105 % |

Referring to FIG. 12 and FIG. 13, the comparative example may be a case in which the second electrode includes AgMg, the electron transport region includes Yb, and AgMg is about 70 angstroms and about 80 angstroms thick, respectively. Example 1 may be a case in which the second electrode includes the first layer (HAT-CN) and the metal thin film layer (Ag), the thickness of the first layer is about 20 angstroms, and the metal thin film layer is about 70 angstroms and about 80 angstroms thick. In Example 2, the second electrode may include the first layer (HAT-CN), the metal thin film layer (Ag), and the holding layer (HAT-CN), the thicknesses of the first layer and the holding layer may be about 20 angstroms, and the metal thin film layer may be about 70 angstroms and about 80 angstroms thick. In the Comparative Examples, it may be confirmed that the sheet resistance changed by about 2.87 and about 2.65 before and after the heat treatment process was performed on the second electrode. On the other hand, it may be confirmed that Example 1 was changed by about 0.94 and about 0.89, and Example 2 was changed by about -0.01 and about -0.05. For example, it may be confirmed that the amount of change in the sheet resistance of the case including the first layer as in Example 1 and of the case including the first layer and the holding layer as in Example 2 was significantly reduced compared to that of the comparative example. The decrease in the amount of change in the sheet resistance may mean that the film quality of the metal thin film layer is improved, and thus, it may be confirmed that the stable second electrode might be provided. It is possible to provide a light emitting device with improved reliability.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A light emitting device comprising:
a first electrode;
a second electrode overlapping the first electrode in a plan view; and
a light emitting part disposed between the first electrode and the second electrode, wherein
the second electrode comprises:
a first layer disposed on the light emitting part, the first layer including a first organic material; and
a metal thin film layer disposed on the first layer, the metal thin film layer including a first metal,
the light emitting part comprises:
an emission layer;
a hole transport region disposed between the first electrode and the emission layer; and
an electron transport region disposed between the emission layer and the second electrode, and
the first layer is disposed on the electron transport region.

2. The light emitting device of claim 1, wherein the first organic material forms a coordination bond with the first metal.

3. The light emitting device of claim 1, wherein the first layer further comprises at least one of a phenanthroline group, a pyrene group, a furan group, and a thiol group.

4. The light emitting device of claim 1, wherein the first layer further comprises a second metal doped into the first organic material.

5. The light emitting device of claim 4, wherein the second metal comprises at least one of Yb, Li, Cu, Ag, Au, Al, and Mg.

6. The light emitting device of claim 1, wherein the first metal of the metal thin film layer is one of Ag, Au, Cu, Al, and Mg.

7. The light emitting device of claim 1, wherein the second electrode further comprises a holding layer disposed on the metal thin film layer.

8. The light emitting device of claim 7, wherein
the holding layer includes a second organic material, and
the second organic material forms a coordination bond with the first metal of the metal thin film layer.

9. The light emitting device of claim 8, wherein the second organic material comprises at least one of a phenanthroline group, a pyrene group, a furan group, and a thiol group.

10. The light emitting device of claim 8, wherein the holding layer includes a third metal doped into the second organic material.

11. The light emitting device of claim 10, wherein the third metal comprises at least one of Yb, Li, Cu, Ag, Au, Al, and Mg.

12. A display device comprising:
a transistor disposed on a substrate; and
a light emitting device electrically connected to the transistor, wherein the light emitting device comprises:
a first electrode;
a second electrode overlapping the first electrode in a plan view; and
a light emitting part disposed between the first electrode and the second electrode,
the second electrode comprises:
a first layer disposed on the light emitting part, the first layer including a first organic material; and
a metal thin film layer disposed on the first layer, the metal thin film layer including a first metal, and
the first organic material comprises at least one of a phenanthroline group, a pyrene group, a furan group, and a thiol group.

13. The display device of claim 12, wherein the first organic material forms a coordination bond with the first metal.

14. The display device of claim 12, wherein the first layer further includes a second metal doped into the first organic material.

15. The display device of claim 14, wherein the second metal comprises at least one of Yb, Li, Cu, Ag, Au, Al, and Mg.

16. The display device of claim 12, wherein the first metal of the metal thin film layer is one of Ag, Au, Cu, Al, and Mg.

17. The display device of claim 12, wherein,
the second electrode further includes a holding layer disposed on the metal thin film layer; and
the holding layer includes a second organic material.

18. The display device of claim 17, wherein the second organic material comprises at least one of a phenanthroline group, a pyrene group, a furan group, and a thiol group.

19. The display device of claim 18, wherein,
the holding layer includes a third metal doped into the second organic material; and
the third metal comprises at least one of Yb, Li, Cu, Ag, Au, Al, and Mg.

20. The display device of claim 17, wherein a thickness of the holding layer is in a range of about 10 angstroms to about 700 angstroms.
